(19) United States
(12) Patent Application Publication
(10) Pub. No.: US 2007/0037359 A1
(43) Pub. Date: Feb. 15, 2007

(54) Method of forming align key in well structure formation process and method of forming element isolation structure using the align key

(75) Inventor: Sung-Il Jo, Bucheon-si (KR)

Correspondence Address: F. CHAU & ASSOCIATES, LLC, 130 WOODBURY ROAD, WOODBURY, NY, 11797, US

(73) Assignee: Samsung Electronics Co., LTD., Suwon-si (KR)

(21) Appl. No.: 11/503,782

(22) Filed: Aug. 14, 2006

(30) Foreign Application Priority Data
Aug. 12, 2005 (KR) 10-2005-0074477

(51) Int. Cl. H01L 21/76

(52) U.S. Cl. 438/401

(57) ABSTRACT

A method of forming an align key in a well structure formation process is provided. The method includes: providing a semiconductor substrate having an align key region and a first well region and forming a first ion implantation mask on the substrate. The first ion implantation mask has a groove exposing a portion of the align key region and covering the first well region. The method further includes etching the exposed align key region and the first ion implantation mask of the first well region to form a trench type align key in the align key region and a second ion implantation mask exposing the first well region, and implanting impurities into the first well region exposed by the second ion implantation mask to form a first well in the first well region.

### CROSS-REFERENCE TO RELATED PATENT APPLICATION

This application claims the benefit of Korean Patent Application No. 10-2005-0074477, filed on Aug. 12, 2005, in the Korean Intellectual Property Office, the disclosure of which is hereby incorporated by reference herein in its entirety.

### BACKGROUND OF THE INVENTION

1. Field of the Invention

The present invention relates to a semiconductor device, and more particularly, to a method of forming an align key for forming an element isolation region and to a method of forming an element isolation structure using the align key.

2. Description of the Related Art

When manufacturing semiconductor devices, a well structure formation process and an element isolation structure formation process are performed in a semiconductor substrate. The element isolation structure formation process is generally defined as a process in which an element isolation structure or a field structure is formed in a semiconductor substrate to define active regions. Typically, the element isolation structure formation process is performed prior to the well structure formation process.

However, the well structure formation process is sometimes performed prior to the element isolation structure formation process in manufacturing certain types of semiconductor devices such as, for example, semiconductor devices having quadro well structures such as power devices, e.g. liquid crystal display driving integrated circuits (ICs).

The above-mentioned power devices such as e.g. the liquid crystal driving IC power devices require high voltage (HV) operation. It is difficult, however, to form a high voltage transistor using a typical twin well structure. Thus, a quadro well structure including deep n-type wells and p-type wells, which are designed for the HV operation, are used in these power devices.

When forming a typical twin well structure, an element isolation structure defining an active region is formed and then a retrograde well is formed. However, deep wells in a quadro well structure require a depth of several to tens of micrometers (μm) in a semiconductor substrate. Moreover, it is difficult to form deep wells using a method of forming retrograde wells because of certain limitations with respect to high energy ion implantation apparatuses.

Accordingly, in certain conventional semiconductor manufacturing processes, a structure having deep wells is formed by performing high temperature well-drive-in process for a long period after performing ion implantation processes. As the high temperature well-drive-in process can degrade the element isolation structure when performed for a long period of time, a well structure formation process for a high voltage driving device or a power device is performed prior to the element isolation structure formation process.

Also, as the active region, which is to be formed subsequently, should be aligned with the well structure formed in the well structure formation process. In addition, an align key aligning the active region with the well structure should also be formed in the well structure formation process on the substrate. Generally, however, processes performed in the well structure formation process do not generate a step, and thus it is difficult to form the align key in the well structure formation process.

Thus, an additional align key forming step should also be performed. The additional align key forming step should be performed before the element isolation structure formation process to align the active region with the well structure. The additional align key forming step may be an additional photolithography process, but an additional photolithography process utilizes an additional photomask, thereby increasing the manufacturing costs for forming the semiconductor device.

Therefore, a method for manufacturing a semiconductor device is needed in which an align key aligning the active region with the well structure can be achieved without having to perform an additional photolithography process.

### SUMMARY OF THE INVENTION

According to an exemplary embodiment of the present invention, there a method of forming an align key in a well structure formation process is provided. The method includes: providing a semiconductor substrate having an align key region and a first well region and forming a first ion implantation mask on the substrate. The first ion implantation mask has a groove exposing a portion of the align key region and covering the first well region. The method further includes etching the exposed align key region and the first ion implantation mask of the first well region to form a trench type align key in the align key region and a second ion implantation mask exposing the first well region, and implanting impurities into the first well region exposed by the second ion implantation mask to form a first well in the first well region.

According to another exemplary embodiment of the present invention, a method of forming an align key in a well structure formation process is provided. The method includes: providing a semiconductor substrate having an align key region, a first well region and a second well region, forming a first ion implantation mask exposing the align key region and the first well region and covering the second well region on the semiconductor substrate. The method further includes implanting first impurities into the first well region exposed by the first ion implantation mask to form a first well in the first well region, etching the exposed the align key region and the first ion implantation mask of the second well region to form a trench type align key in the align key region and a second ion implantation mask exposing the second well region, and implanting second impurities into the second well region exposed by the second ion implantation mask to form a second well in the second well region

The forming of the second ion implantation mask may include: forming a second photoresist layer covering the first ion implantation mask, forming a second photoresist pattern exposing the first ion implantation mask of the second well region and the align key region exposed in the groove by performing a photolithography process on the second photoresist layer using the groove as a align key for exposure alignment, and etching the exposed portion of the first ion implantation mask and the exposed align key region using the second photoresist pattern as an etch mask.

The method may further include: implanting third impurities in at least substantially the entire substrate to form a third well before forming the first ion implantation mask. The third impurities have opposite conductivity type to the first impurities.

Each of the wells may be formed to a depth of about 1.0 to about 12 μm for a high voltage device driven with a high voltage of about 15 to about 30 V.

According to still another exemplary embodiment of the present invention, a method of forming an element isolation structure is provided. The method includes: providing a semiconductor substrate having an align key region and a first well region, forming a first ion implantation mask on the substrate. The first ion implantation mask has a groove exposing a portion of the align key region and covers the first well region. The method further includes forming a second ion implantation mask exposing the first well region and a trench type align key in the align key region by etching the first ion implantation mask of the first well region and the align key region exposed in the groove, implanting impurities into the first well region exposed by the second ion implantation mask to form a first well, removing the second ion implantation mask, and forming an element isolation structure aligned with the first well using the trench type align key as a reference point.

The element isolation structure may be a shallow trench isolation (STI) structure.

The forming of the element isolation structure may include: forming a trench in the semiconductor substrate using a photolithography process and an etching process in which exposure alignment is performed using the trench type align key as a reference point, and forming an insulation layer filling the trench.

The forming of the element isolation structure may further include: chemical mechanical polishing (CMP) the insulation layer to separate the insulating layer into the element isolation structure.

### BRIEF DESCRIPTION OF THE DRAWINGS

FIGS. 1 through 11 are cross-sectional views for illustrating a method of forming an align key for forming an element isolation region in the formation of a well structure according to an exemplary embodiment of the present invention;

FIGS. 12 through 18 are cross-sectional views for illustrating a method of forming an element isolation structure according to an exemplary embodiment of the present invention; and

FIG. 19 is a plan view of an align key according to an exemplary embodiment of the present invention.

### DETAILED DESCRIPTION OF THE EXEMPLARY EMBODIMENTS OF THE INVENTION

Hereinafter, the present invention will be described more fully with reference to the accompanying drawings, in which exemplary embodiments of the invention are shown. The invention may, however, be embodied in many different forms and should not be construed as being limited to the embodiments set forth herein

In exemplary embodiments of the present invention, a well structure including deep wells, for example a quadro well structure used in a high voltage device, is formed. Subsequently, an element isolation structure defining an active region is formed. Moreover, in exemplary embodiments of the present invention, a trench is formed during a photolithography process for defining well regions in a well structure formation process, and then is used as an align key to align the active region with the well structure.

Generally, when a deep well structure is formed with diffused wells, a subsequent process of producing a shallow trench isolation (STI) cannot be performed with an align key having a step. However, with the exemplary embodiments of the present invention, the photolithography and etching processes, can be used to form a well align key aligning a well with a formerly formed well and an element isolation structure align key, thereby aligning an active region with the well structure.

Also, with the exemplary embodiments, the well align key may be formed as a groove in an ion implantation mask which includes silicon nitride. In addition, the element isolation structure align key is formed as a trench in a semiconductor substrate by etching the substrate when the ion implantation mask is patterned. For example, in a first etching process, a layer is patterned to form the ion implantation mask and a well align key which is a groove in the ion implantation mask. Subsequently, in a second etching process, a portion of the substrate exposed in the groove is etched to form the trench type element isolation structure align key.

The region where the trench is formed is a region exposed through the photoresist patterns during two photolithography processes of the well structure formation process. Accordingly, the region where the trench is to be formed is exposed in the first photolithography process, and then the exposed substrate region is selectively etched in the second photolithography process. Consequently, the trench may be formed in the substrate and the trench may provide a step between the surface of the substrate and the bottom of the trench.

Furthermore, with exemplary embodiments of the present invention, an additional photomask and an additional layer to form the element isolation structure align key are not required. Although the position of an align key in a conventional photomask or a reticle used in the well structure formation process may be changed to form the align key in the substrate, the additional photomask is still not required. Further, since the layer for forming the ion implantation mask is also used as a layer for forming the well align key, an additional layer for forming the well align key is not required.

Moreover, when forming the trench used as the element isolation structure align key in the substrate in the well structure formation process, the etching conditions may be optimized. The optimization of the etching conditions can be sufficiently established by changing the present dry etching conditions. Also, by optimizing the etching conditions, an additional etching process may not be necessary.

Furthermore, in exemplary embodiments of the present invention, the generation of a step in regions of the substrate other than an align key region (or a scribe region) can be prevented. For example, regions of the substrate other than the align key region are not exposed during etching processes, and thus these portions cannot be etched.

Except for the align key region (or scribe region), the substrate does not include steps, and thus undesired steps are not generated in an active region after the element isolation structure formation process. In addition, when an element isolation structure formation process is performed using STI and CMP processes, the STI and CMP processes are performed on a substantially flat substrate. Accordingly, a CMP process margin and the planarity of a hard mask for STI can be obtained, and the occurrence of nitride residue from a nitride layer used as the hard mask in the formation of STI can be prevented.

The hard mask which is used in the formation of STI is used as a polishing termination layer when a CMP process is performed after an insulation layer is filled in an isolation trench. When the hard mask has inferior planarity, it is difficult to uniformly detect a polishing termination point, and thus excessive CMP will occur in some regions. In other regions, the insulation layer may remain on the hard mask, and thus the removal of the hard mask after CMP may be prevented, so that the hard mask may still remain. Accordingly, the CMP process margin for forming STI becomes too narrow.

In contrast to the conventional semiconductor processes, with the exemplary embodiments of the present invention, since a step is not generated in regions of the substrate other than the align key region, a sufficient CMP process margin can be ensured and/or the occurrence of nitride residue can effectively be prevented.

Exemplary embodiments of the present invention will now be described with a well structure including a p-type substrate, n-type well (NW), p-type well (PW) and P-pocket well (PPW). That is, there are three or more wells which are formed through a well-drive-in process. However, the exemplary embodiments of the present invention are not limited thereto but rather may be applied to a well structure having a plurality of wells, for example, three or more wells.

The well structures in the drawings according to exemplary embodiments of the present invention are examples of well structures including wells with a depth ranging from about 1.0 to about 12 μm designed for a high voltage device of about 15 to about 120 V, preferably about 15 to about 30 V.

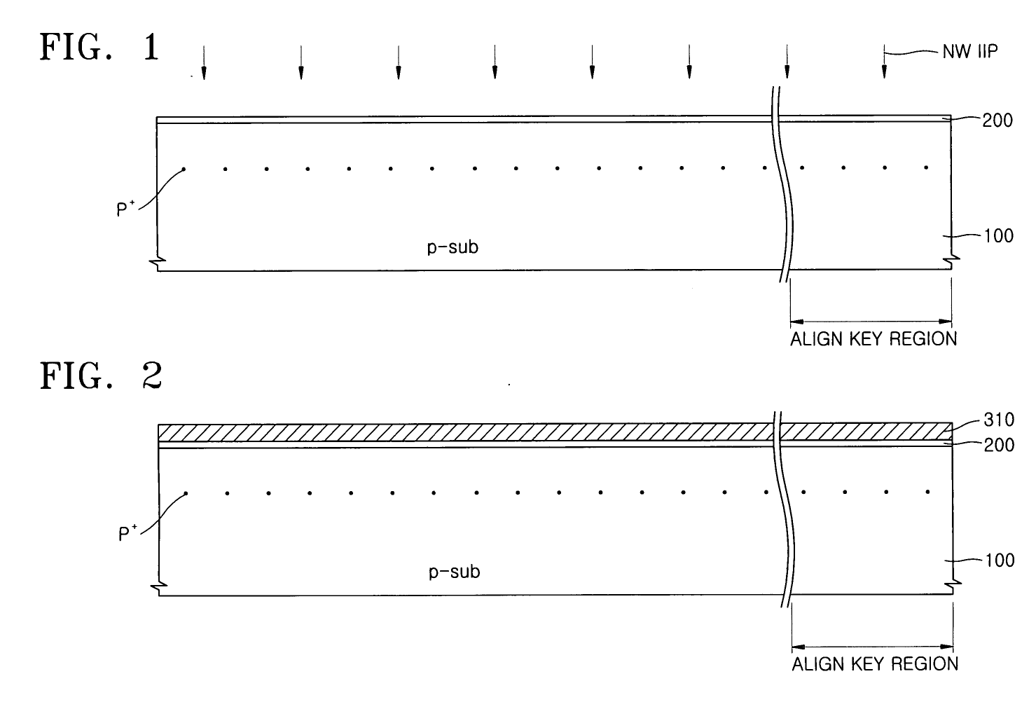

FIGS. 1 through 11 are cross-sectional views for illustrating a method of forming an align key for forming an element isolation region in a well structure formation process according to an exemplary embodiment of the present invention.

Referring to FIG. 1, a pad layer 200 is formed on a semiconductor substrate 100, for example, the substrate doped with p-type impurities. The substrate 100 may include an align key region where an align key is to be formed and element regions where elements are to be formed. The align key region is formed in a scribe region.

The pad layer 200 may have a silicon oxide layer. The pad layer 200 may be formed to a thickness of about 200 to about 500 angstroms (Å), preferably about 300 to about 400 Å, using a thermal oxidation method.

First ion implantation is performed on the entire region of the substrate 100. The first ion implantation may be a process of implanting impurities having opposite conductivity to the impurities previously doped in the substrate 100. For example, n-type impurities, such as phosphonate ions (P⁺), can be implanted into the substrate 100. The first ion implantation is high energy ion implantation. That is, P⁺ ions at a dosage of about 1.5E13 ions/cm³ are accelerated at about 2.0 MeV for the implantation.

The first ion implantation may be N-well ion implantation (NW IIP) for forming n-type well (NW). The first ion implantation forms a first impurity layer in which P⁺ ions are implanted, in the entire or substantially the entire region of substrate 100.

Referring to FIG. 2, an ion implantation mask layer 310 is formed on the pad layer 200. An ion implantation mask defines well regions when a well structure having a plurality of wells is formed. For example, the ion implantation mask can define a P-well region in a N-well region. The ion implantation mask may be formed by patterning the ion implantation mask layer 310 made of, for example, silicon nitride. The ion implantation mask layer 310 may be formed by depositing silicon nitride to a thickness of about 1000 Å. The thickness of the ion implantation mask layer 310 may be varied, by taking into consideration the thickness of the pad layer 200, which will be a factor in a subsequent process of forming a trench type align key.

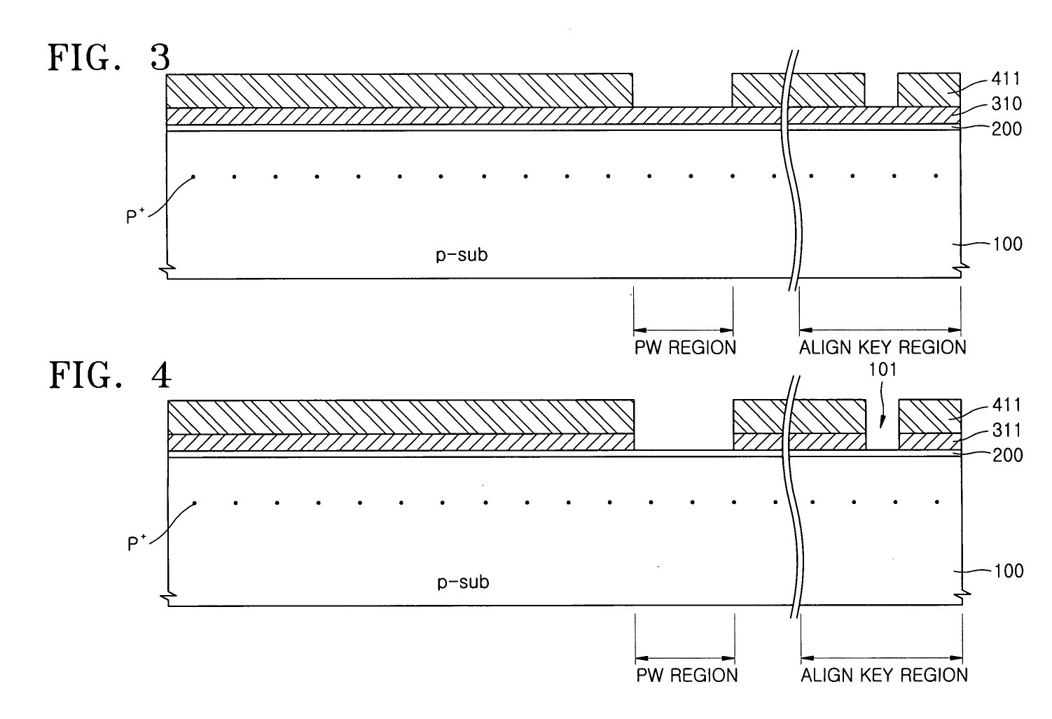

Referring to FIG. 3, a first photoresist pattern 411 is formed on the ion implantation mask layer 310. The first photoresist pattern 411 is formed in a first photolithography process. For example, a photoresist layer can be formed on the ion implantation mask layer 310, then exposed and developed to form the first photoresist pattern 411. The first photoresist pattern 411 may expose a p-type well (PW) region where a PW is to be formed. Here, the first photoresist pattern 411 may expose a portion of the align key region of the substrate 100 to form a well align key.

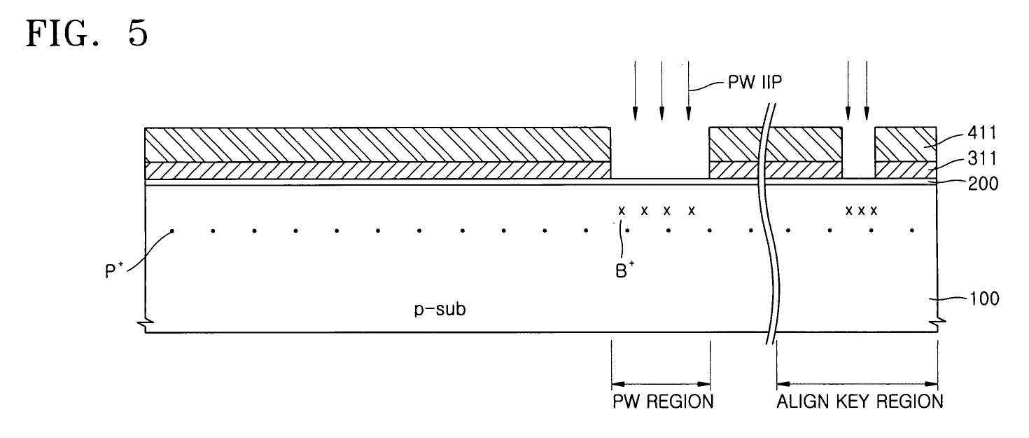

Referring to FIG. 4, the exposed portion of the ion implantation mask layer 310 is etched to form the first ion implantation mask 311 using the first photoresist pattern 411 as an etch mask. The etching process is a dry etching process having an etch selectivity between photoresist and silicon nitride, using the pad layer 200 as an etch termination layer. The first ion implantation mask 311 has a pattern corresponding to the first photoresist pattern 411. Accordingly, the first ion implantation mask 311 exposes the pad layer 200 of the PW region and has a groove 101 in which the pad layer 200 of the align key region is exposed. Referring to FIG. 5, a second ion is implanted into the substrate 100 where the first ion implantation mask 311 is formed. The second ion implantation may be a process of implanting impurities having opposite conductivity to the impurities used in the first ion implantation. For example, p-type impurities, such as boron ions (B⁺) can be implanted.

The second ion implantation is a high energy ion implantation. That is, B⁺ ions at a dosage of about 1.8E12 to about 1.8E13 ions/cm³ are accelerated at about 700 to about 800 KeV for the implantation. In an exemplary embodiment of the present invention, the second ion implantation is performed with the B⁺ ions at a dosage of about 1.8E13 ions/cm³ accelerated at about 700 KeV.

The second ion implantation may be a P-well ion implantation (PW IIP) for forming p-type well, that is, P well (PW). In the second ion implantation, the p-type impurities are selectively implanted into a predetermined region of the substrate 100 exposed through the first ion implantation mask 311 and/or the first photoresist pattern 411. That is, a second impurity region having B⁺ ions is formed in the PW region and a portion of the align key region of the substrate 100.

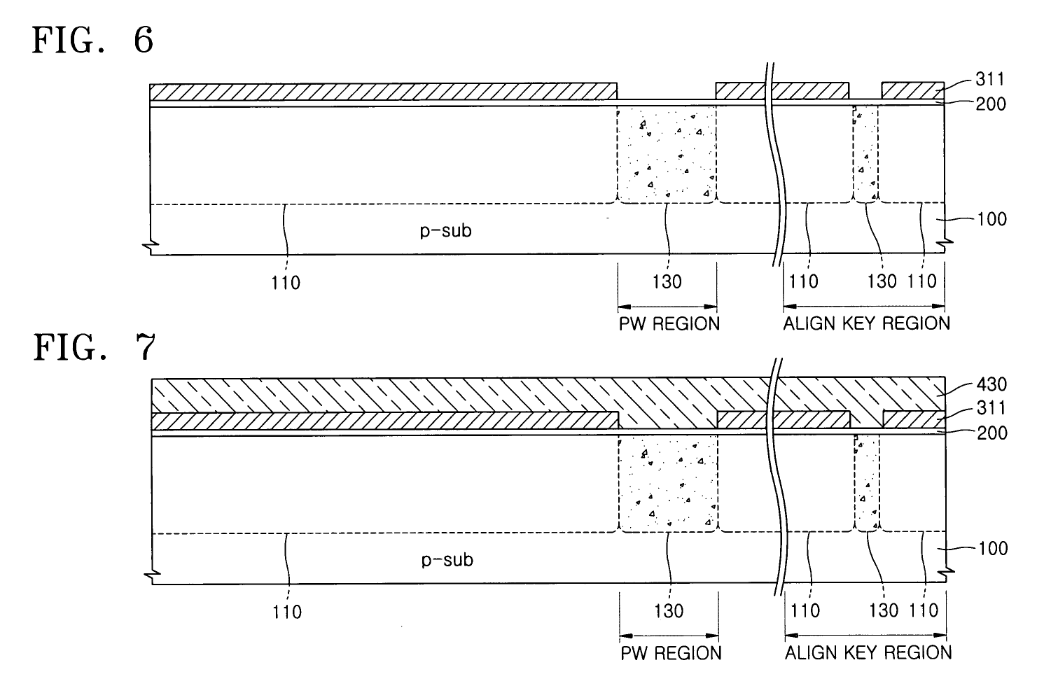

Referring to FIG. 6, a first well-drive-in process is performed with the substrate 100. The first well-drive-in process may be a high temperature, long-period heat-treatment, in which the ion implanted impurities are diffused to form wells having a deep depth of, for example, about 1.0 to about 12 μm, which may be used in a high voltage device with a high voltage of about 15 to about 30 V. In the well-drive-in process, the first heat-treatment is performed at about 1100 to about 1150° C. for about 8 to about 13 hours to diffuse the implanted impurities. For example, the first well-drive-in process can be performed at about 1150° C. for about 8 hours.

Accordingly, PWs 130, that is, second wells, are formed in the regions exposed through the first ion implantation mask 311 and/or the first photoresist pattern 411, for example, the PW region and a portion of the align key region. Additionally, NWs 110, that is, first wells, which are defined by the PWs 130, are formed in another region of the substrate 100.

The first photoresist pattern 411 may be stripped for removal before performing the first well-drive-in process.

Referring to FIG. 7, a second photoresist layer 430 is formed on the first ion implantation mask 311.

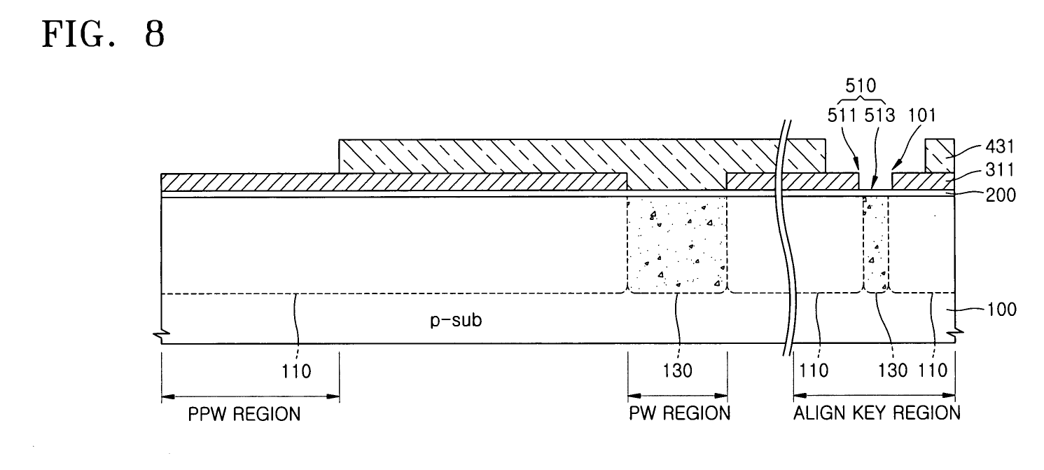

Referring to FIG. 8, a second photoresist pattern 431 is formed by exposing the second photoresist layer 430 through a second photolithography process. The second photoresist pattern 431 exposes the first ion implantation mask 311 of the PPW region and the groove 101. For example, the second photoresist pattern 431 exposes the pad layer 513 exposed in the groove 101 and a well align key pattern 511 adjacent to the exposed pad layer 513. The well align key pattern 511 is a portion of the first ion implantation mask 311. The second photoresist pattern 431 may expose a wide region of the upper surface of the well align key pattern 511, or may expose only the exposed pad layer 513.

During the exposure process of the second photolithography process, exposure alignment is performed using the groove 101 as an align key, that is, a reference point. Moreover an align key in a first photomask having a transfer pattern for forming the second photoresist pattern 431 and the groove 101 are aligned, and thereby the second photoresist pattern 431 exposes the regions where the PPWs are formed. The groove 101 has a step 510 between the well align key pattern 511 and the exposed pad layer 513. Thus, the exposure alignment is performed in a second photolithography process using the step 510 as an align key.

The first ion implantation mask 311 having the groove 101 exposes the PW region. Therefore, the exposed PPW region through the second photoresist pattern 431 can be aligned with the PW region as well as the groove 101.

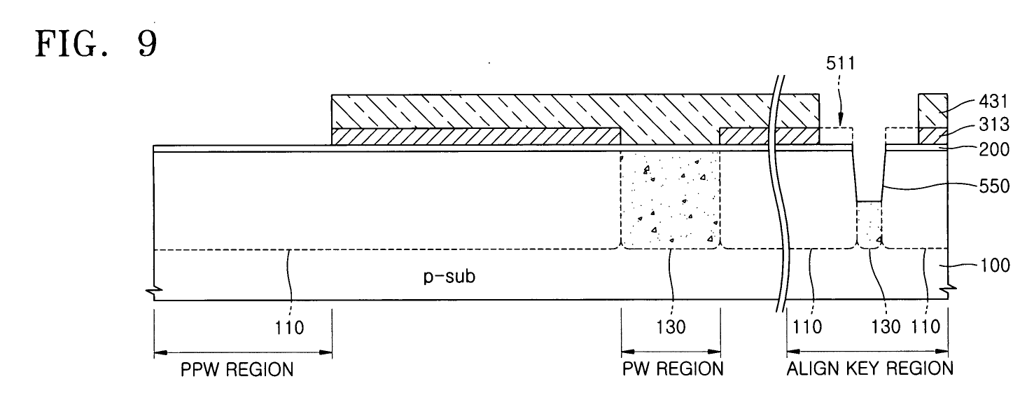

Referring to FIG. 9, the exposed portion of the first ion implantation mask 311 is selectively etched to form the second ion implantation mask 313 using the second photoresist pattern 431 as an etch mask. The etching process is, for example, a dry etching process having an etch selectivity between photoresist and silicon nitride using the pad layer 200 under the first ion implantation mask 311 as an etch termination layer.

A second ion implantation mask 313 formed using the second photoresist pattern 431 is prepared for forming a P-pocket well (PPW), that is, a third well, in the NW 110.

The second photoresist pattern 431 corresponds to the pattern formed in the second ion implantation mask 313 by etching. Accordingly, the second ion implantation mask 313 exposes portions of pad layer 200 corresponding to the PPW region.

The second photoresist pattern 431 exposes the well align key pattern 511 and the pad layer 513, as illustrated in FIG. 8. Accordingly, during the etching process using the second photoresist pattern 431 as an etch mask, the exposed pad layer 513 in the align key region may be etched. In addition, the substrate 100 exposed by the etching of the pad layer 513 is continuously etched, thereby forming a trench. Accordingly, the trench, that is, a trench type align key 550 is formed in the align key region of the semiconductor substrate 100.

The exposed portion of the first ion implantation mask 311 may have a thickness of about 1000 Å. Although the pad layer 200 is a silicon oxide layer, and thus can be used as an etch termination layer because of the etch selectivity between silicon oxide and the second ion implantation mask 313, which is formed of silicon nitride, the exposed portion 513 of the pad layer 200 (see FIG. 8) may be sufficiently etched to be removed in the etching process. In addition, a portion of the semiconductor substrate 100 under the pad layer 200 is selectively etched to a sufficient depth to form a trench when the portion of the first ion implantation mask 311 is etched for removal.

If desired, the dry etching conditions for patterning the second ion implantation mask 313 in the etching process may be used to induce the formation of the trench. For example, a dry etching process may be employed in which the etch selectivity of the first ion implantation mask 311 to the silicon in the semiconductor substrate 100 is relatively low or the etch selectivity of the first ion implantation mask 311 to the pad layer 200 is relatively low, and the second ion implantation mask 313 may be selectively etched for patterning. Thus, the portion 513 of the pad layer 200 and the portion of the semiconductor substrate 100 under the portion 513 of the pad layer 200 may be etched to form a trench.

The trench may provide a step between the surface of the semiconductor substrate 100 and the bottom of the trench. Accordingly, in the subsequent element isolation structure formation process, the step can be used as an align key in the exposure alignment process defining the element isolation region and/or the active region. In other words, the trench 550 can be used as an element isolation structure align key.

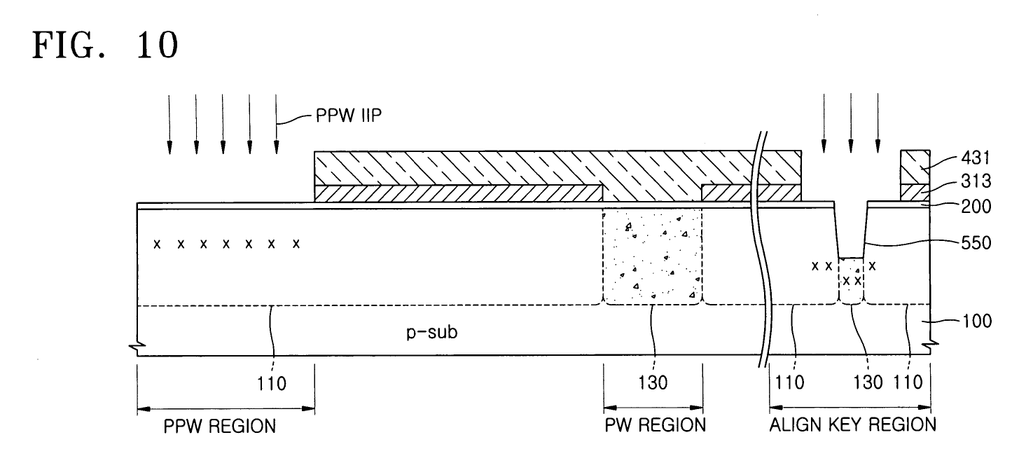

Referring to FIG. 10, third ion implantation is performed through the second ion implantation mask 313 and/or the second photoresist pattern 431 into the semiconductor substrate 100. The third ion implantation may be a process of implanting impurities having opposite conductivity to the impurities used in the first ion implantation. For example, p-type impurities, such as boron ions (B⁺) may be implanted.

The third ion implantation forms third wells and may be, for example, P-pocket well ion implantation (PW IIP) for forming p-type pocket wells (PPWs). In the third ion implantation, the p-type impurities are selectively implanted in a predetermined region of the semiconductor substrate 100 exposed through the second ion implantation mask 313 and/or the second photoresist pattern 431. That is, a third impurity region having B⁺ ions is formed in the PPW region and a portion of the align key region of the semiconductor substrate 100.

The third ion implantation may be used to form pocket wells in the NW 110. The third ion implantation is high energy ion implantation. That is, B⁺ ions at a dosage of about 1.8E12 to 1.8E13 ions/cm³ are accelerated at about 700 to about 800 KeV for the implantation. In an exemplary embodiment of the present invention, the third ion implantation is performed with the B⁺ ions at a dosage of about 1.8E13 ions/cm³ accelerated at about 700 KeV.

Referring to FIG. 11, a second well-drive-in process is performed in the semiconductor substrate 100. The second well-drive-in process may be a high temperature, long-period heat-treatment, in which the ion implanted impurities are diffused to form pocket wells having a deep depth of, for example, about 1.0 to about 12 μm, which may be used in a high voltage device driven with a high voltage of about 15 to about 30 V. In the well-drive-in process, the first heat-treatment is performed at about 1100 to about 1150° C. for about 8 to about 13 hours to diffuse the ion implanted impurities. For example, the first well-drive-in process can be performed at about 1150° C. for about 8 hours.

Accordingly, PPWs 150, that is, third wells, are formed in regions of the semiconductor substrate 100 exposed through the second ion implantation mask 313 and/or the second photoresist pattern 431, for example, the PWW region and a portion of the align key region. The PPWs 150 are surrounded by the NWs 110, that is, the first wells.

The second photoresist pattern 431 may be stripped for removal before forming the second well-drive-in process.

According the present exemplary embodiment, a portion of the align key region in the semiconductor substrate 100 is exposed by performing two photolithography processes in a well structure formation process, and then a portion of the exposed align key region of the semiconductor substrate 100 can be selectively etched during the second etching process. Accordingly, a trench, which is formed by etching a portion of the semiconductor substrate 100 in a well structure formation process, can be used as an element isolation structure align key 550 defining an active region (or an element isolation region) in a subsequent element isolation structure process.

When the trench is formed in the align key region of the semiconductor substrate 100, the generation of well steps in other element regions of the semiconductor substrate 100 are prevented, as illustrated in FIG. 11. Accordingly, difficulties occurring in a subsequent process performed on the element region of the semiconductor substrate 100, for example, a difficulty caused by the well steps, is prevented.

The ion implantation masks 311 and 313 and the photoresist patterns 411 and 431 in the above described ion implantation process may act as a mask in the ion implantation processes.

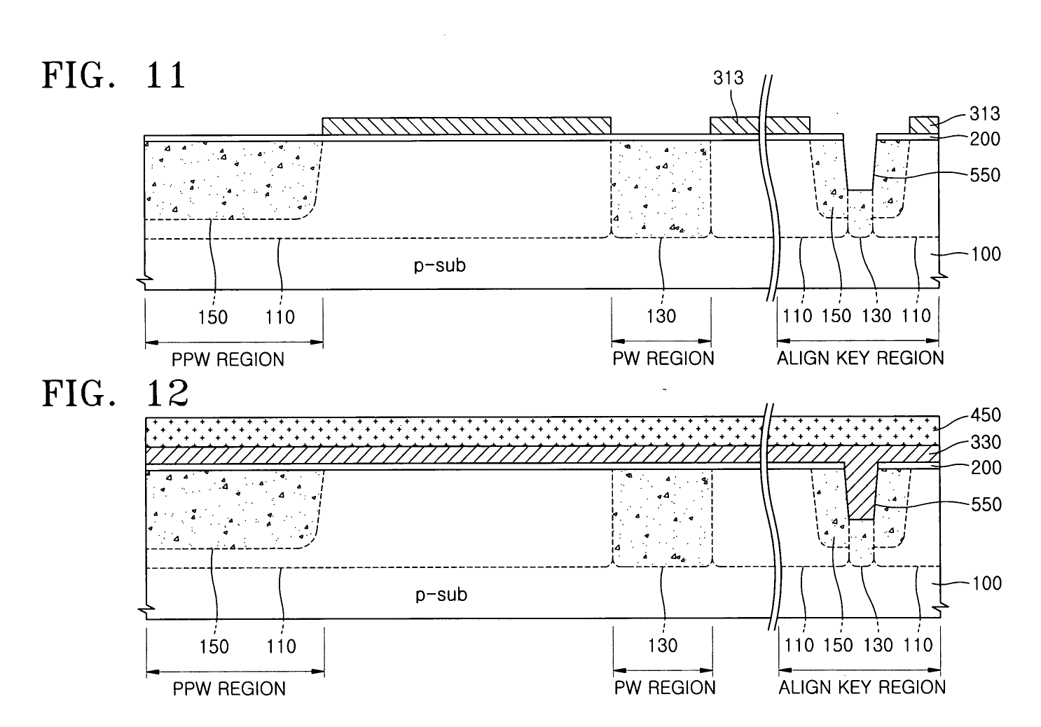

FIGS. 12 through 18 are cross-sectional views for illustrating a method of forming an element isolation structure using a trench type align key according to an exemplary embodiment of the present invention. In the present exemplary embodiment, the element isolation structure is an STI element isolation structure, but the exemplary embodiments of the present invention are not limited thereto.

Referring to FIG. 12, the second ion implantation mask 313 is removed from the semiconductor substrate 100 having the deep well structure, and then a hard mask layer 330 and a third photoresist layer 450 for patterning the hard mask layer 330 are sequentially formed on the semiconductor substrate 100.

The hard mask layer 330 may be used as an etch mask in a STI process, and/or may form a hard mask used as an etch termination layer in a subsequent CMP process. The hard mask layer 330 may be formed of silicon nitride. The third photoresist layer 450 may define the element isolation region in the third photolithography process.

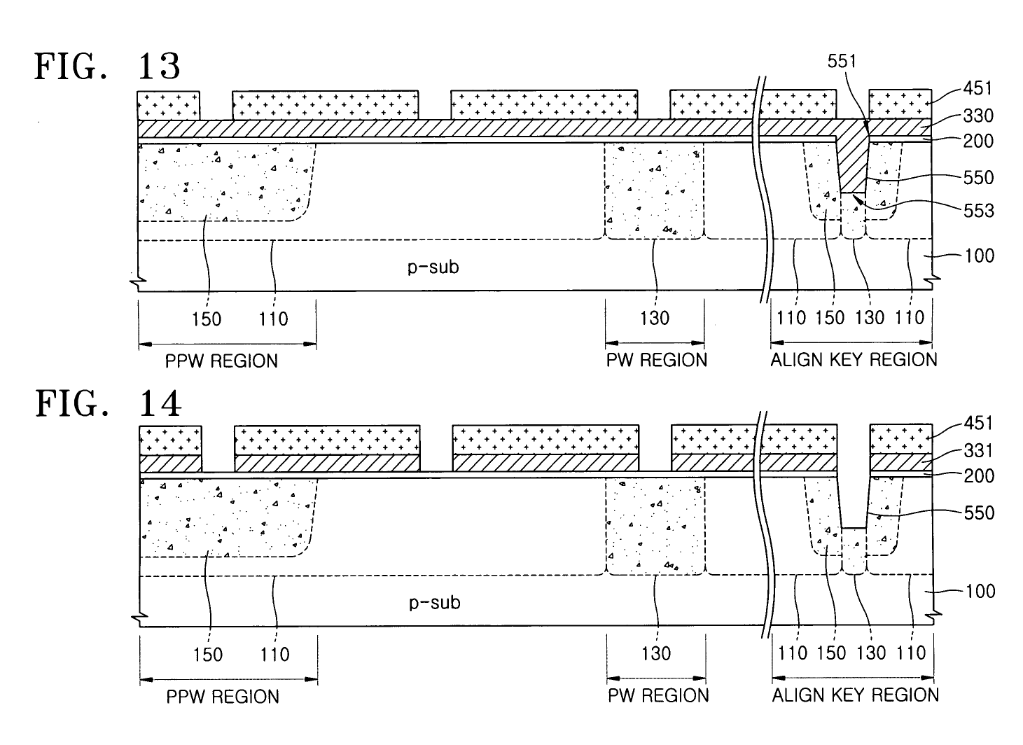

Referring to FIG. 13, a third photoresist pattern 451 is formed form the third photoresist layer 450. For example, a third photolithography process is performed on the third photoresist layer 450 to expose a region which will be an element isolation region, thereby forming the third photoresist pattern 451. During the exposure process of the third photolithography process, exposure alignment may be performed using the trench type align key 550. For example, using a step between the top 551 and bottom 553 of the trench type align key 550 as a reference point, the exposure alignment between a second photomask and the substrate 100 can be performed during the exposure process of the third photolithography.

The third photoresist pattern 451 may be used to expose the element isolation region and the trench type align key 550 because this is beneficial when removing the hard mask layer 330 filled in the trench type align key 550 in a subsequent process.

Referring to FIG. 14, the exposed hard mask layer 330 is selectively etched using the third photoresist pattern 451 as an etch mask to form a hard mask 331. Accordingly, the hard mask 331 exposes the element isolation region.

Referring to FIG. 15, the exposed region of the semiconductor substrate 100 is selectively etched to form trenches 610 for element isolation using the hard mask 331 and/or the third photoresist pattern 451 as an etch mask. The third photoresist pattern 331 may be selectively stripped for removal.

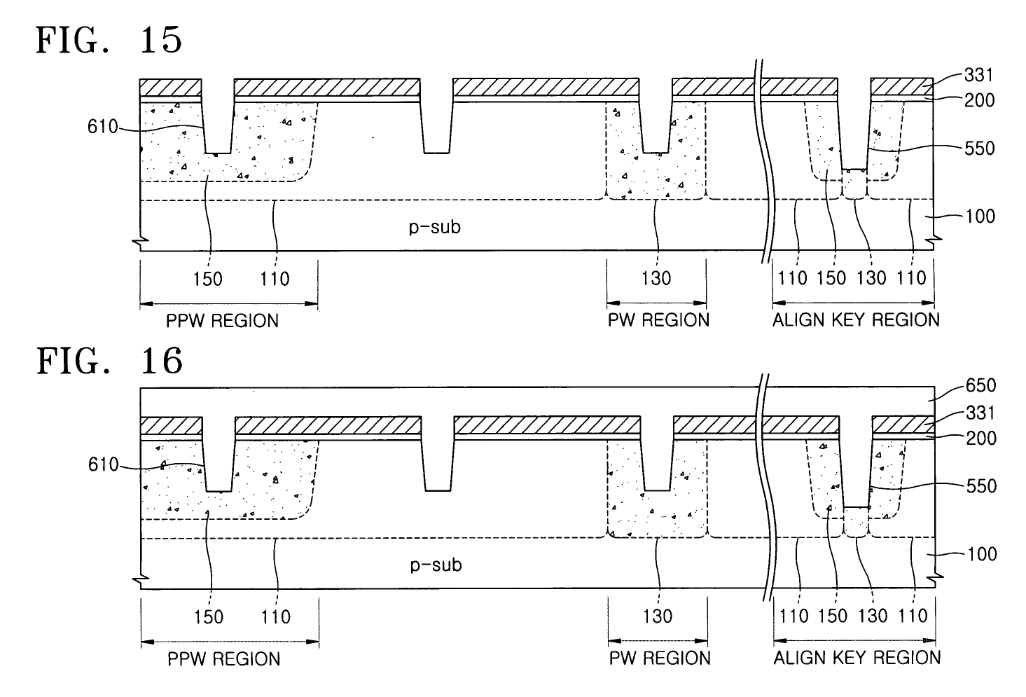

Referring to FIG. 16, an insulation layer 650 filling the trenches 610 is formed. The insulation layer 650 may be formed of an insulation material, for example, silicon oxide, and cover the hard mask 331.

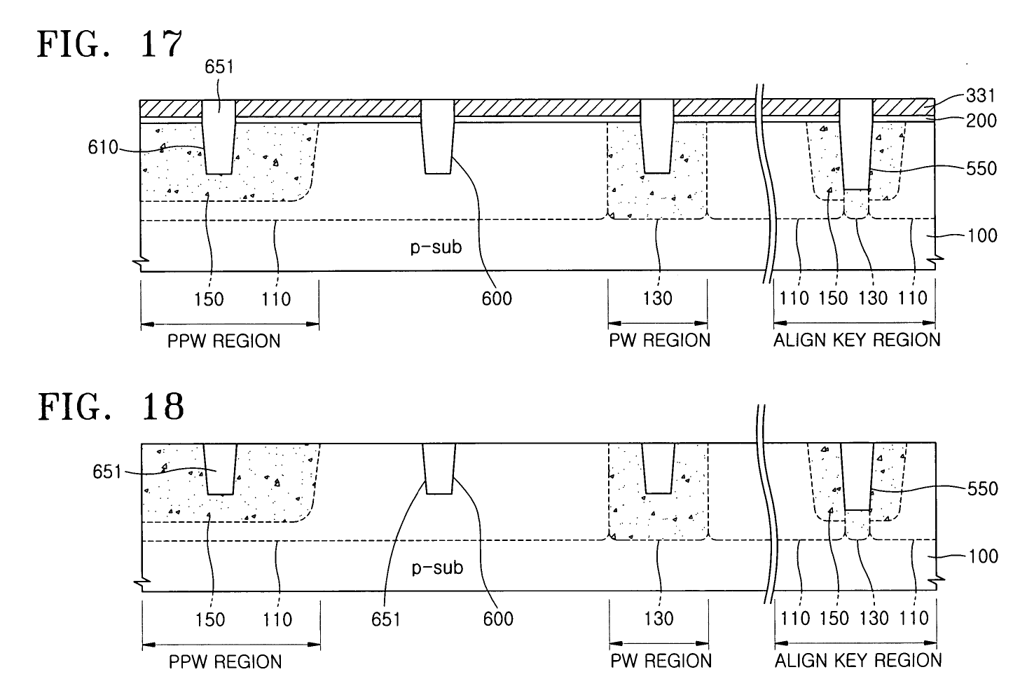

Referring to FIG. 17, the insulation layer 650 is separated into element isolation units 651. In this exemplary embodiment a CMP process is employed for separating the insulation layer 650. The CMP process is chosen due to its beneficial properties with regard to planarizing the semiconductor substrate 100. However, various methods known in the art can be utilized for separating the insulation layer 650. Also, the hard mask 331 is used as a polishing termination layer when performing the CMP process on the insulation layer 650.

Additionally, in the current exemplary embodiment, a step region such as a well step is generated in an insubstantial amount in the element region of the semiconductor substrate 100, and thus the thickness of the hard mask 331 is uniform. Since the hard mask 331 having a uniform thickness can be used as a polishing termination layer, the polishing termination layer can be readily detected during the CMP process. Accordingly, with the exemplary embodiments, a sufficient CMP process margin is provided, and CMP defects such as nitride residue or pattern defects in the element isolation units 651 are effectively prevented.

Referring to FIG. 18, the hard mask 331 and the pad layer 200 thereunder are selectively removed to complete the element isolation units 651. The element isolation units 651 define an active region of the semiconductor substrate 100.

According to the exemplary embodiments of the present invention described above, the well align key 510 is formed in a well structure formation process and the element isolation structure align key 550 is formed as a trench in the semiconductor substrate 100 in a well structure formation process.

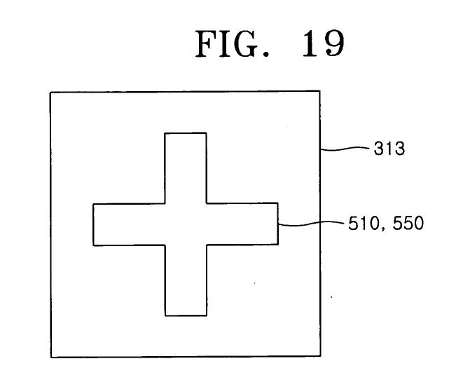

FIG. 19 is a plan view of an align key according to an exemplary embodiment of the present invention.

The align keys 510 and 550 can have various shapes such as, for example, a cross shape. If they have a cross shaped layout, as illustrated in FIG. 19, the exposure alignment is easier to achieve since the alignment in the x and y directions is easier to control.

According to the exemplary embodiments of the present invention, when a deep well structure formation process is performed prior to the formation of an element isolation structure, an element isolation structure align key used in the formation of the element isolation structure can be provided with a trench formed in a semiconductor substrate in the well structure formation process.

The element isolation structure align key may be formed as a trench in only an align key region in a photolithography process and an etching process for forming a well structure. Accordingly, regions, such as element regions, in the semiconductor substrate other than the align key region do not have well steps.

Therefore, defects caused by the well steps, for example, lack of a CMP process margin for STI and/or the occurrence of nitride residue, are prevented in the subsequent element isolation structure process.

As the element isolation structure align key is formed in the well structure formation process, an additional photomask is not required and/or an additional process for forming a layer is not necessary. Accordingly, an element isolation structure align key can be formed without an additional process.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of forming an align key in a well structure formation process, the method comprising:
providing a semiconductor substrate having an align key region and a first well region;
forming a first ion implantation mask on the substrate, the first ion implantation mask having a groove exposing a portion of the align key region and covering the first well region;
etching the exposed align key region and the first ion implantation mask of the first well region to form a trench type align key in the align key region and a second ion implantation mask exposing the first well region; and
implanting impurities into the first well region exposed by the second ion implantation mask to form a first well in the first well region.

2. The method of claim 1, further comprising:
forming a pad layer on the substrate before forming the first ion implantation mask,
wherein the first ion implantation mask is etched using the pad layer disposed under the first ion implantation mask as an etch termination layer,
wherein the exposed align key region is etched by etching the pad layer and the substrate of the align key region.

3. The method of claim 2, wherein the pad layer has silicon oxide layer with a thickness of about 200 to about 500 Å

4. The method of claim 2, wherein the first ion implantation mask is comprised of silicon nitride and has a greater thickness than the pad layer such that at least some of the first ion implantation mask of the first well region remains until etching the pad layer of the align key region and the substrate disposed under the pad layer in forming the second ion implantation mask.

5. The method of claim 4, wherein the first ion implantation mask has a thickness of about 1000 Å.

6. The method of claim 1, wherein the substrate has a second well region,
wherein the forming of the first ion implantation mask comprises forming an ion implantation mask layer on the substrate;
forming a first photoresist pattern on the ion implantation mask layer, the first photoresist pattern exposes the ion implantation mask layer of the second well region and the align key region; and etching the exposed ion implantation mask layer using the first photoresist pattern as an etch mask.

7. The method of claim 1, wherein the forming of the trench type align key and the second ion implantation mask comprises:
forming a second photoresist layer covering the first ion implantation mask;
forming a second photoresist pattern exposing the first ion implantation mask of the first well region and the align key region exposed in the groove by performing a photolithography process on the second photoresist layer using the groove as a align key for exposure alignment; and
etching the exposed portion of the first ion implantation mask and the exposed align key region using the second photoresist pattern as an etch mask.

8. The method of claim 1, wherein the first well is formed to a depth of about 1.0 to about 12 μm for a high voltage device driven with a high voltage of about 15 to about 30 V.

9. A method of forming an align key in a well structure formation process, the method comprising:
providing a semiconductor substrate having an align key region, a first well region and a second well region; forming a first ion implantation mask exposing the align key region and the first well region and covering the second well region on the semiconductor substrate;
implanting first impurities into the first well region exposed by the first ion implantation mask to form a first well in the first well region;
etching the exposed align key region and the first ion implantation mask of the second well region to form a trench type align key in the align key region and a second ion implantation mask exposing the second well region; and
implanting second impurities into the second well region exposed by the second ion implantation mask to form a second well in the second well region.

10. The method of claim 9, further comprising:
forming a pad layer on the substrate before forming the first ion implantation mask,
wherein the first ion implantation mask is etched using the pad layer disposed under the first ion implantation mask as an etch termination layer,
wherein the exposed align key region is etched by etching the pad layer and the substrate under the pad layer.

11. The method of claim 10, wherein the first ion implantation mask is comprised of silicon nitride and has a greater thickness than the pad layer such that at least some of the first ion implantation mask remains until etching the pad layer of the align key region and the substrate disposed under the pad layer in forming the second ion implantation mask.

12. The method of claim 9, wherein forming the first ion implantation mask comprises:
forming an ion implantation mask layer on the semiconductor substrate;
forming a first photoresist pattern on the ion implantation mask layer, the first photoresist pattern exposes the ion implantation mask layer of the first well region and the align key region; and
forming the first ion implantation mask by etching the ion implantation mask layer using the first photoresist pattern as an etch mask.

13. The method of claim 9, further comprising:
performing a first heat treatment to form the first well as a diffused deep well after the implanting of the first impurities.

14. The method of claim 13, wherein the first well is formed to a depth of about 1.0 to about 12 μm for a high voltage device driven with a high voltage of about 15 to about 30 V.

15. The method of claim 9, wherein the forming of the trench type align key and the second ion implantation mask comprises:
forming a second photoresist layer covering the first ion implantation mask;
forming a second photoresist pattern exposing the first ion implantation mask of the second well region and the align key region exposed in the groove by performing a photolithography process on the second photoresist layer using the groove as a align key for exposure alignment; and
etching the exposed portion of the first ion implantation mask and the exposed align key region using the second photoresist pattern as an etch mask.

16. The method of claim 9 further comprising:
performing a second heat treatment to form the second well as a diffused deep well after the implanting of the second impurities.

17. The method of claim 16, wherein the second well is formed to a depth of about 1.0 to about 12 μm for a high voltage device driven with a high voltage of about 15 to about 30 V.

18. The method of claim 9, further comprising:
implanting third impurities in at least substantially the entire substrate to form a third well before forming the first ion implantation mask, the third impurities have opposite conductivity type to the first impurities.

19. The method of claim 18, further comprising: performing a first heat treatment to form the first and third wells as diffused deep wells after the implanting of the first impurities.

20. The method of claim 18, wherein the second well is formed as pocket well aligned in the third well.

21. A method of forming an align key in a well structure formation process, the method comprising:
providing a semiconductor substrate having an align key region, a first well region and a second well region;
forming a pad layer on the substrate;
forming a first ion implantation mask on the pad layer, the first ion implantation mask exposes the first well region and has a groove exposing the pad layer of the align key region;
implanting first impurities into the first well region exposed by the first ion implantation mask to form a first well in the first well region;
forming a photoresist layer covering the first ion implantation mask;
forming a photoresist pattern exposing the first ion implantation mask of the second well region and the pad layer exposed in the groove by performing a photolithography process on the photoresist layer using the groove as a align key for exposure alignment;
forming a trench type align key in the align key region and a second ion implantation mask exposing the second well region by etching the exposed first ion implantation mask, the exposed pad layer, the semiconductor substrate under the pad layer using the second photoresist pattern as an etch mask; and
implanting second impurities into the second well region exposed by the second ion implantation mask to form a second well in the second well region.

22. The method of claim 21, wherein the first ion implantation mask is comprised of silicon nitride and has a greater thickness than the pad layer such that at least some of the first ion implantation mask remains until etching the pad layer of the align key region and the substrate disposed under the pad layer in forming the second ion implantation mask.

23. The method of claim 21, wherein the forming of the first ion implantation mask comprises:
forming an ion implantation mask layer on the semiconductor substrate;
forming a first photoresist pattern on the ion implantation mask layer, the first photoresist pattern exposes the ion implantation mask layer of the first well region and the align key region; and
forming the first ion implantation mask by etching the ion implantation mask layer using the first photoresist pattern as an etch mask.

24. The method of claim 21, further comprising:
implanting third impurities in at least substantially the entire substrate to form a third well before forming the first ion implantation mask, the third impurities have opposite conductivity type to the first impurities.

25. The method of claim 24, further comprising:
performing a first heat treatment to form the first and third wells as diffused deep wells after the implanting of the first impurities.

26. The method of claim 25, wherein the third well has a depth of about 1.0 to about 12 μm for a high voltage device driven with a high voltage of about 15 to about 30 V.

27. The method of claim 24, wherein the second well is formed as pocket well aligned in the third well.

28. A method of forming an element isolation structure comprising:
providing a semiconductor substrate having an align key region and a first well region; forming a first ion implantation mask on the substrate, the first ion implantation mask has a groove exposing a portion of the align key region and covering the first well region;
forming a second ion implantation mask exposing the first well region and a trench type align key in the align key region by etching the first ion implantation mask of the first well region and the align key region exposed in the groove;
implanting impurities into the first well region exposed by the second ion implantation mask to form a first well;
removing the second ion implantation mask; and
forming an element isolation structure aligned with the first well using the trench type align key as a reference point.

29. The method of claim 28, further comprising:
forming a pad layer on the semiconductor substrate before forming the first ion implantation mask,
wherein the first ion implantation mask is etched using the pad layer disposed under the first ion implantation mask as an etch termination layer,
wherein the exposed align key region is etched by etching the pad layer and the substrate of the align key region.

30. The method of claim 29, wherein the first ion implantation mask is comprised of silicon nitride and has a greater thickness than the pad layer such that at least some of the first ion implantation mask of the first well region remains until etching the pad layer of the align key region and the substrate disposed under the pad layer in forming the second ion implantation mask.

31. The method of claim 28, wherein forming the first ion implantation mask comprises:
forming an ion implantation mask layer on the semiconductor substrate;
forming a first photoresist pattern on the ion implantation mask layer, the first photoresist pattern exposes the ion implantation layer of the first well region and the align key region; and
forming the first ion implantation mask by etching the ion implantation mask layer using the first photoresist pattern as an etch mask.

32. The method of claim 28, wherein forming the second ion implantation mask comprises:
forming a second photoresist layer covering the first ion implantation mask;
forming a second photoresist pattern exposing the first ion implantation mask of the first well region and the align key region exposed in the groove by performing a photolithography process on the second photoresist layer using the groove as a align key for exposure alignment; and
etching the exposed portion of the first ion implantation mask and the exposed align key region using the second photoresist pattern as an etch mask.

33. The method of claim 28, wherein the first well is formed to a depth of about 1.0 to about 12 μm for a high voltage device driven with a high voltage of about 15 to about 30 V.

34. The method of claim 28, wherein the element isolation structure is a shallow trench isolation (STI) structure.

35. The method of claim 28, wherein the forming of the element isolation structure comprises:
forming a trench in the semiconductor substrate using a photolithography process and an etching process in which exposure alignment is performed using the trench type align key as a reference point; and
forming an insulation layer filling the trench.

36. The method of claim 35, wherein the forming of the element isolation structure further comprises:
chemical mechanical polishing (CMP) the insulation layer to separate the insulating layer into the element isolation structure.

37. A method of forming an element isolation structure comprising:
providing a semiconductor substrate having an align key region, a first well region and a second well region;
forming a first ion implantation mask on a semiconductor substrate, the first ion implantation mask exposes the first well region and has a groove exposing a portion of the align key region;
implanting first impurities into the first well region exposed through the first ion implantation mask to form a first well in the first well region;
forming a second ion implantation mask exposing a second well region and a trench type align key in the align key region by etching the first ion implantation mask and the align key region exposed in the groove;
implanting second impurities into the second well region exposed by the second ion implantation mask;
removing the second ion implantation mask; and
forming an element isolation structure in the substrate, the element isolation structure is aligned with the well using the align key as a reference point.

38. The method of claim 37, wherein the forming of the second ion implantation mask comprises:
forming a second photoresist layer covering the first ion implantation mask;
forming a second photoresist pattern exposing the first ion implantation mask of the first well region and the align key region exposed in the groove by performing a photolithography process on the second photoresist layer using the groove as a align key for exposure alignment; and
etching the exposed portion of the first ion implantation mask and the exposed align key region using the second photoresist pattern as an etch mask.

39. A method of forming an element isolation structure comprising:
forming an pad layer on a semiconductor substrate having an align key region, a first well region and a second well region;
forming a first ion implantation mask on the pad layer, the first ion implantation mask exposes the first well region and has a groove exposing a portion of the align key region;
implanting first impurities into the first well region exposed through the first ion implantation mask;
forming a photoresist layer covering the first ion implantation mask;
forming a photoresist pattern exposing the first ion implantation mask of the second well region and the align key region exposed in the groove by performing a photolithography process on the second photoresist layer using the groove as a align key for exposure alignment;
forming a trench type align key in the align key region and a second ion implantation mask exposing the second well region by etching the exposed first ion implantation mask, the exposed pad layer, the semiconductor substrate under the pad layer using the second photoresist pattern as an etch mask;
implanting second impurities into the second well region exposed through the second ion implantation mask to form a second well in the second well region;
removing the second ion implantation mask; and
forming an element isolation structure in the substrate, the element isolation structure is aligned with the well using the align key as a reference point.

40. The method of claim 39, further comprising:
implanting third impurities in at least substantially the entire substrate to form a third well before forming the first ion implantation mask, the third impurities have opposite conductivity type to the first impurities.

41. The method of claim 39, wherein the forming of the element isolation structure comprises:
forming a trench in the semiconductor substrate using a photolithography process and an etching process in which exposure alignment is performed using the trench type align key as a reference point; and
forming an insulation layer filling the trench.
